(19) United States
(12) Patent Application Publication
(10) Pub. No.: US 2006/0016561 A1
(43) Pub. Date: Jan. 26, 2006

(54) Semiconductor etching apparatus

(76) Inventors: Sung-Sok Choi, Suwon-si (KR); Jin-Jun Park, Seoul (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/148,192

(22) Filed: Jun. 9, 2005

(30) Foreign Application Priority Data
Jul. 20, 2004 (KR) 2004-56176

(51) Int. Cl. H01L 21/306; C23F 1/00

(52) U.S. Cl. 156/345.51; 156/915

(57) ABSTRACT

A semiconductor etching apparatus includes an electrostatic chuck, an edge ring and a spacer. The electrostatic chuck includes a ring mounting part. The edge ring has an outer part and an inner part. The outer part has a thickness greater than a height of the ring mounting part, and the inner part is disposed to be proximate to the vertical surface of the ring mounting part. Upper and lower surfaces of the inner part are stepped upward and downward, respectively, by the same height from upper and lower surfaces of the outer part. The spacer is ring-shaped, is disposed on a horizontal surface of the ring mounting part, supports the inner part of the edge ring member, and has a thickness that is the same as the height between the lower surface of the outer part and the upper surface of the inner part of the edge ring member.

### CROSS REFERENCE TO RELATED APPLICATIONS

This application claims priority under 35 U.S.C. §119 from Korean Patent Application 2004-56176, filed on Jul. 20, 2004, the contents of which are hereby incorporated by reference in their entirety for all purposes as if fully set forth herein.

### BACKGROUND AND SUMMARY

1. Technical Field

The present invention relates to a semiconductor etching apparatus capable of performing an entirely uniform etching on a wafer by controlling an etching rate on an edge of wafer and a flow of reactive gas.

2. Description

An etching technology to manufacture semiconductor devices is generally used to form a desired pattern from layer material formed on a semiconductor substrate, and an etching apparatus is needed for such a process.

In particular, an etching apparatus to form a pattern may be a plasma etching apparatus or dry etching apparatus, and such an etching apparatus is mainly used for a technology requiring a design rule under 0.15 μm.

FIG. 1 illustrates a dry etching apparatus. Referring to FIG. 1, a process chamber 10 includes an electrostatic chuck 11 on which a wafer W is mounted. A lower electrode 12 is provided below electrostatic chuck 11. An upper electrode 13 is provided at a predetermined distance above electrostatic chuck 11.

Reactive gas is supplied to the process chamber from above, or from a side of, process chamber 10 where upper electrode 13 is provided.

Under a state where wafer W is stably mounted on electrostatic chuck 11 of process chamber 10, reactive gas is supplied into the process chamber, and also an RF bias is applied to lower electrode 12 and upper electrode 13. Accordingly, plasma is generated on wafer W and this plasma collides with layer material of wafer W, performing an etching.

In the etching process of wafer W using plasma, an outer side or edge of the wafer W provided on electrostatic chuck 11 is surrounded by a focus ring 14 that is also generally referred to as a top ring, so that plasma can be concentrated and collected onto wafer W.

The most important issue in such an etching process is the uniformity of wafer etching.

Plasma generated by a supply of reactive gas and an applied RF bias is generally formed in an oval shape on the wafer W, and the vertical movement of the plasma ions colliding with the wafer W is satisfactory in the center of the wafer, but the collision angle becomes gradually more acute toward the edge of the wafer W, as shown in FIG. 2 illustrating the collision of plasma on such an edge portion.

With reference to FIG. 2, an upper surface of electrostatic chuck 11 onto which wafer W is mounted has an outer diameter smaller than an outer diameter of wafer W, and is recessed toward the inside of electrostatic chuck 11 so as to have a stepped shape.

An edge ring 15, formed of the same material as wafer W, is equipped within the stepped portion of electrostatic chuck 11, and supports an edge surface of wafer W from beneath, together with electrostatic chuck 11.

Focus ring 14 is provided outside of edge ring 15. Focus ring 14 and edge ring 15 are mounted on a shadow ring 16 that is mounted at an outer circumference of an upper surface of lower electrode 12.

However, plasma distributed in an oval shape on wafer W becomes slow and has an acute collision angle, particularly on an edge of wafer W, which causes the wafer W to have a slanted etching pattern as shown in FIG. 3 and simultaneously not to be etched to a required depth, thus causing a lot of pattern defects, such as unopened trenches or holes, on an edge portion of wafer W.

Such defects lower the production yield of semiconductor devices and reduce the productivity and reliability of the resultant devices.

Accordingly, it would be desirable to provide a semiconductor etching apparatus exhibiting improved vertical collision characteristics of plasma ions on the edge of the wafer to produce a uniform etching rate on an entire surface of wafer. Furthermore, it would be desirable if the edge ring of the apparatus could be used when “flipped over,” thereby extending its useful life.

According to one aspect of the invention, a semiconductor etching apparatus includes an electrostatic chuck, an edge ring member and a spacer within a process chamber. A circumferal area of a top portion of the electrostatic chuck is recessed by a fixed distance down to a fixed depth to form a stepped-down ring mounting part. The edge ring member has an outer part and an inner part in one body. The outer part has a thickness greater than a height of a vertical surface of the ring mounting part of the electrostatic chuck, and the inner part is projected inwardly from an inner diameter surface of the outer part so as to be proximate to the vertical surface of the ring mounting part. An upper surface and a lower surface of the inner part are stepped upward and downward, respectively, by a same height from inner diameter upper and lower surfaces of the outer part. The spacer member has a ring shape, is disposed on a horizontal surface of the ring mounting part of the electrostatic chuck, is adapted to support a lower surface of the inner part of the edge ring member, and has a thickness that is the same as the height between the lower surface of the outer part and the upper surface of the inner part of the edge ring member.

According to another aspect of the invention, the formation range of plasma formed on an upper surface of a wafer is extended through the edge ring member and the spacer member for extending an area outwardly, and simultaneously an electric field or magnetic field is in contact with such plasma, thereby accelerating a collision speed of plasma ions colliding with the wafer, at least at an edge of the wafer.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 is a sectional view illustrating a side section part of a conventional etching apparatus;

FIG. 2 is an enlarged sectional view partially illustrating a collision state of plasma ions on an edge of a wafer in a conventional etching apparatus;

FIG. 3 is an enlarged sectional view partially illustrating a pattern defect example on an edge of a wafer in a conventional etching apparatus;

FIG. 4 is a sectional view of main components of a semiconductor etching apparatus according to a first exemplary embodiment;

FIG. 5 is a sectional view illustrating a separation state of the main components of FIG. 4 according to a first exemplary embodiment;

FIG. 6 is a perspective view illustrating half sections of separated edge ring member and spacer member according to a first exemplary embodiment;

FIG. 7 is a sectional view illustrating a side section according to a second exemplary embodiment;

FIG. 8 is a plan view illustrating an installation structure of an electromagnet member according to a second exemplary embodiment;

FIG. 9 is a sectional view illustrating a side section according to a third exemplary embodiment;

FIG. 10 is a plan view illustrating an installation structure of a magnet member according to a third exemplary embodiment;

FIG. 11 is a perspective view according to a fourth exemplary embodiment; and

FIG. 12 is a sectional view illustrating a side part according to a fourth exemplary embodiment.

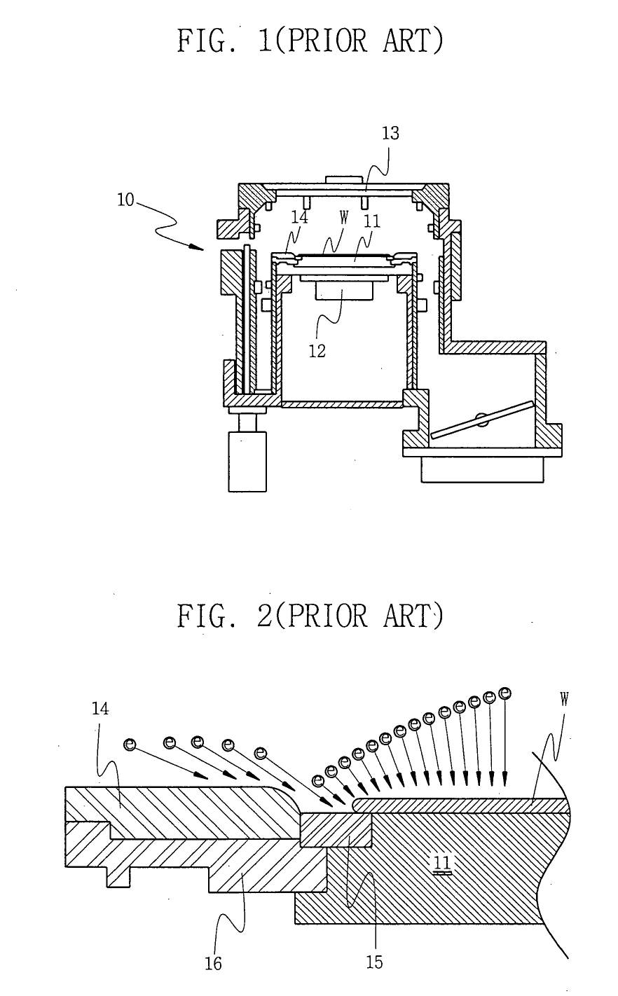

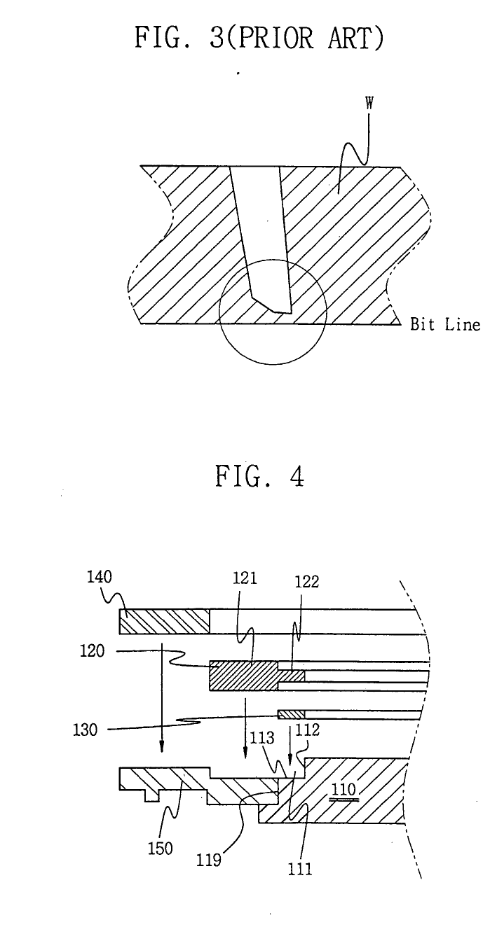

### DETAILED DESCRIPTION

Hereinafter, exemplary embodiments will be described in detail with reference to FIGS. 4 to 12. It will be understood by those skilled in the art that the present invention can be embodied in numerous different forms, and is not limited to the following described embodiments. The following various embodiments are exemplary in nature.

[First Exemplary Embodiment]

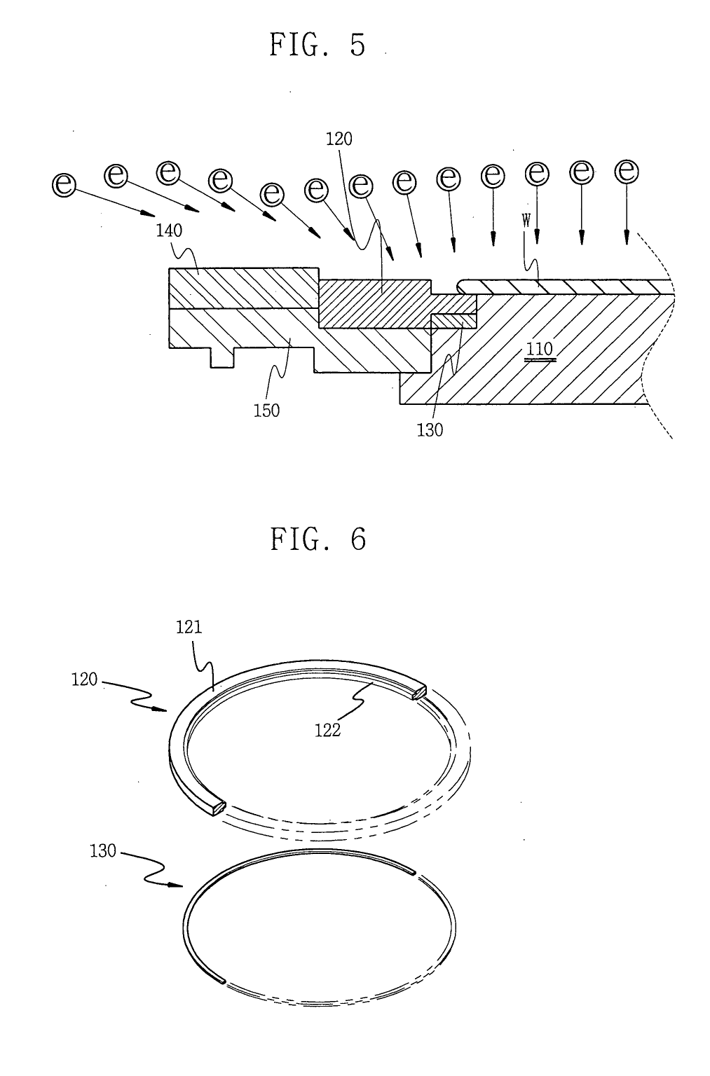

FIG. 4 is a sectional view of main components of a semiconductor etching apparatus according to a first exemplary embodiment. FIG. 5 denotes an enlarged sectional view illustrating a separation state of the main components of FIG. 4, and FIG. 6 designates a perspective view of an edge ring member and spacer member shown in FIGS. 4 and 5.

As shown in the drawings, according to a first exemplary embodiment, a circumferal area of an upper portion of an electrostatic chuck 110 on which a wafer is mounted is recessed by a fixed distance toward an inside thereof down to a predetermined depth to form a stepped-down ring mounting part 111. The circumferal area of the upper portion of the electrostatic chuck 110 is understood to mean the area at the outer circumference of the electrostatic chuck 110 near its top surface. That is, as shown in FIG. 4, the outer circumference of the very top surface of the electrostatic chuck 110, defined by the vertical surface 112, is less than the circumference of the stepped-down base portion 113 of the ring mounting part 111, defined by the vertical surface 119.

In this arrangement, an upper surface of electrostatic chuck 110 is smaller than a diameter of a wafer W mounted on electrostatic chuck 110.

An edge ring member 120 is provided at ring mounting part 111 so as to prevent etching of an edge of electrostatic chuck 110. More particularly, edge ring member 120 and a spacer member 130 are mounted on base portion (horizontal surface) 113 of ring mounting part 111 formed at the circumferal area of the upper portion of electrostatic chuck 110. Edge ring member 120 has a configuration where an outer part 121 and an inner part 122, each being ring-shaped and having mutually different thicknesses, are connected in one body. Beneficially, edge ring member 120 comprises a same material as wafer W. Spacer member 130 supports side and lower surfaces of inner part 122 of edge ring member 120 so that edge ring member 120 always maintains a predetermined height.

Outer part 121 of edge ring member 120 has a thickness that is greater than a height of a vertical surface 112 of ring mounting part 111 formed at the circumferal area of the upper surface of electrostatic chuck 110. An inner diameter of outer part 121 is equal to or greater than an inner diameter of ring mounting part 111. Inner part 122 of edge ring member 120 is formed being projected inwardly from an inner diameter surface of outer part 121 so as to be proximate to vertical surface 112 of ring mounting part 111. An upper surface and a lower surface of inner part 122 are stepped downward and upward, respectively, by the same height from inner diameter upper and lower surfaces of outer part 121.

In other words, in forming outer part 121 and inner part 122 of edge ring member 120, a predetermined length is extended inwardly from an inner diameter surface of outer part 121, and a thickness of the formed length is reduced both downward and upward by an equal height from an upper surface and a lower surface of outer part 121, respectively, and thus inner part 122 is formed with a reduced thickness. That is, a height between an upper surface of outer part 121 of edge ring member 120 and an upper surface of inner part 122 is equal to a height between a lower surface of outer part 121 and a lower surface of inner part 122.

Furthermore, the height from a lower surface of outer part 121 to an upper surface of inner part 122 is the same as the height of vertical surface 112 of ring mounting part 111. Also, inner part 122 of edge ring member 120 has such a diameter that an inner diameter surface of inner part 122 is proximate to and almost in contact with vertical surface 112 of ring mounting part 111 of electrostatic chuck 110.

In edge ring member 120, beneficially a width of outer part 121 is between 8.0˜14.0 mm and a width of inner part 122 is between 0.5˜2.5 mm.

In inner part 122 of the edge ring member 120, the upper surface and the lower surface are processed to have a mirror-like finish, and in outer part 121, the upper surface and the lower surface are processed roughly by a lapping process.

Meanwhile, spacer member 130, provided at the lower surface of the inner part 122 of the edge ring member 120, has a thickness corresponding to a stepped height between outer part 121 and inner part 122 of edge ring member 120, and has a flat bottom so as to be mounted on base portion 113 of ring mounting part 111 of the electrostatic chuck 110.

Spacer member 130 is formed in such a size that an inner diameter surface can become proximate to vertical surface 112 of the ring mounting part 111 of electrostatic chuck 110, and beneficially a width of the spacer member 130 may be in a range from 0.2˜2.5 mm.

A focus ring 140 is provided outside of edge ring member 120. Focus ring 140 and edge ring member 120 are mounted on a shadow ring 150 that is mounted at an outer circumference of electrostatic chuck 110 at a portion beneath the ring mounting part 111.

[Second Exemplary Embodiment]

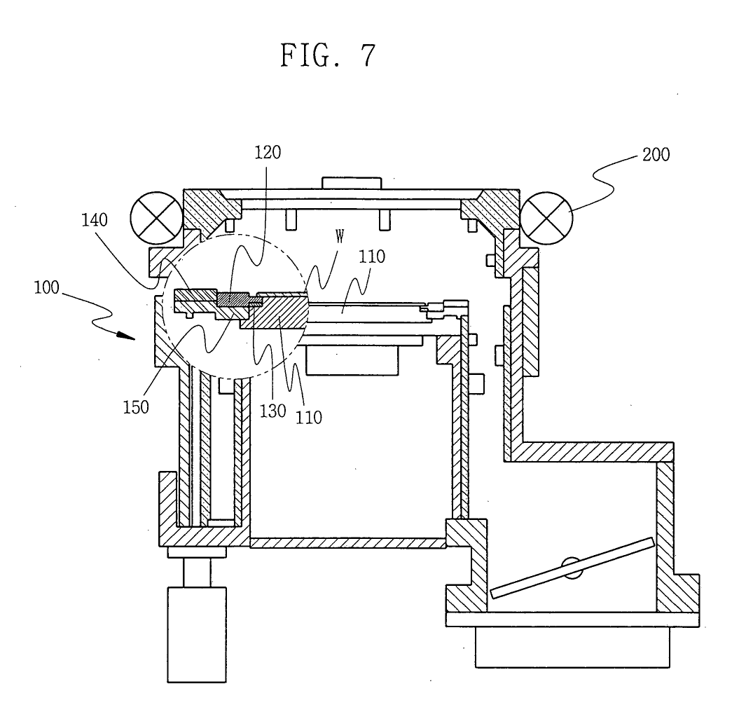

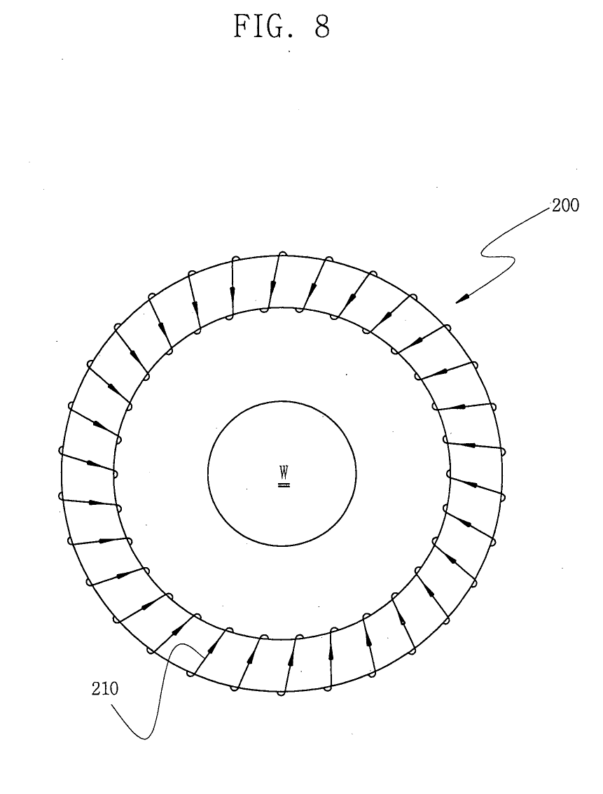

FIGS. 7 and 8 illustrate a second exemplary embodiment, and in the following described exemplary embodiments, like reference symbols are used for like components.

As in the first exemplary embodiment, a circumferal area of an upper portion of an electrostatic chuck 110 on which a wafer is mounted is recessed by a fixed distance toward an inside thereof down to a predetermined depth to form a stepped-down ring mounting part 111. That is, as shown in FIG. 4, the outer circumference of the very top surface of the electrostatic chuck 110, defined by the vertical surface 112, is less than the circumference of the stepped-down base portion 113 of the ring mounting part 111, defined by the vertical surface 119.

In this arrangement, an upper surface of electrostatic chuck 110 is smaller than a diameter of a wafer W mounted on electrostatic chuck 110.

Edge ring member 120 is provided on ring mounting part 111 so as to prevent etching of an edge of electrostatic chuck 110. More particularly, an edge ring constructed of edge ring member 120 and spacer member 130 are mounted in ring mounting part 111 formed at a circumferal area of the upper surface of electrostatic chuck 110, and such a configuration is the same as the above-described first exemplary embodiment.

That is, edge ring member 120 has a configuration wherein outer part 121 and inner part 122, each being ring-shaped and having mutually different thicknesses, are connected in one body, and spacer member 130 supports side and lower surfaces of inner part 122 of edge ring member 120 so that edge ring member 120 always maintains a predetermined height.

Outer part 121 of the edge ring member 120 has a thickness that is greater than a height of vertical face 112 of ring mounting part 111 formed at the circumferal area of the upper portion of electrostatic chuck 110. An inner diameter of the outer part 121 is equal to or larger than an inner diameter of ring mounting part 111. Inner part 122 of edge ring member 120 is formed being projected inwardly from an inner diameter surface of outer part 121 so as to be proximate to vertical surface 112 of ring mounting part 111. An upper part and a lower part of inner part 122 are stepped upward and downward, respectively, by the same height from inner diameter upper and lower surfaces of the outer part 121. In other words, the height between the upper surface of outer part 121 and the upper surface of inner part 122 of edge ring member 120 is equal to the height between a lower surface of outer part 121 and a lower surface of inner part 122.

Furthermore, the height from a lower surface of the outer part 121 to an upper surface of the inner part 122 is equal to the height of the vertical surface 112 of the ring mounting part 111. Also, inner part 122 of edge ring member 120 has such a diameter that an inner diameter surface of inner part 122 is proximate to and almost in contact with vertical surface 112 of ring mounting part 111 of electrostatic chuck 110.

Beneficially, the width of outer part 121 of edge ring member 120 is between 8.0˜14.0 mm, and the width of inner part 122 is between 0.5˜2.5 mm.

An upper surface and a lower surface of inner part 122 of edge ring member 120 are processed to have a mirror-like finish, and an upper surface and a lower surface of outer part 121 are processed roughly by a lapping process.

Meanwhile, pacer member 130 is formed as a flat plate to be mounted on a horizontal surface of ring mounting part 111 in electrostatic chuck 110, with a thickness corresponding to the height of a step between outer part 121 and inner part 122 of edge ring member 120. In spacer member 130, an inner diameter surface is formed having a size sufficient to be proximate to vertical surface 112 of the electrostatic chuck 110. Beneficially, spacer member 130 may have a width of 0.2˜2.5 mm.

A focus ring 140 is provided outside of edge ring member 120. Focus ring 140 and edge ring member 120 are mounted on a shadow ring 150 that is mounted at an outer circumference of electrostatic chuck 110 at a portion beneath the ring mounting part 111.

The configuration of the edge ring member 120 and the spacer member 130 provided at the ring mounting part 111 of the electrostatic chuck 110 is the same as that of the first exemplary embodiment. However, the second exemplary embodiment includes an electromagnet member 200 provided in particular on an upper outer wall of process chamber 100, where electromagnet member 200 is formed by winding a conductive coil around a ring-shaped core of magnetic material (e.g., iron).

As shown in FIG. 8, electromagnet member 200 is obtained by winding an electromagnetic coil 210 having a ring-shaped iron core shape several times, and is provided in a shape surrounding an outer surface of process chamber 100. Electromagnet member 200 is fixed to an outer wall of process chamber 100 at a position higher than the plasma formation height in process chamber 100.

When a power source is applied to such electromagnet member 200 so that current flows in the direction indicated by the arrows in the drawing, the electric field has a downward direction according to the Faraday principle, thus the collision speed of plasma ions formed on wafer W is increased.

At this time, plasma ions are accelerated and so an etching characteristic is improved not only in the center but also at an edge of wafer W.

In other words, the plasma formation range is further increased by edge ring member 120, and also an electric field is in contact with plasma so that plasma is accelerated toward a wafer, thereby an etching having a sufficient vertical depth can be performed in particular on the edge of wafer W.

[Third Exemplary Embodiment]

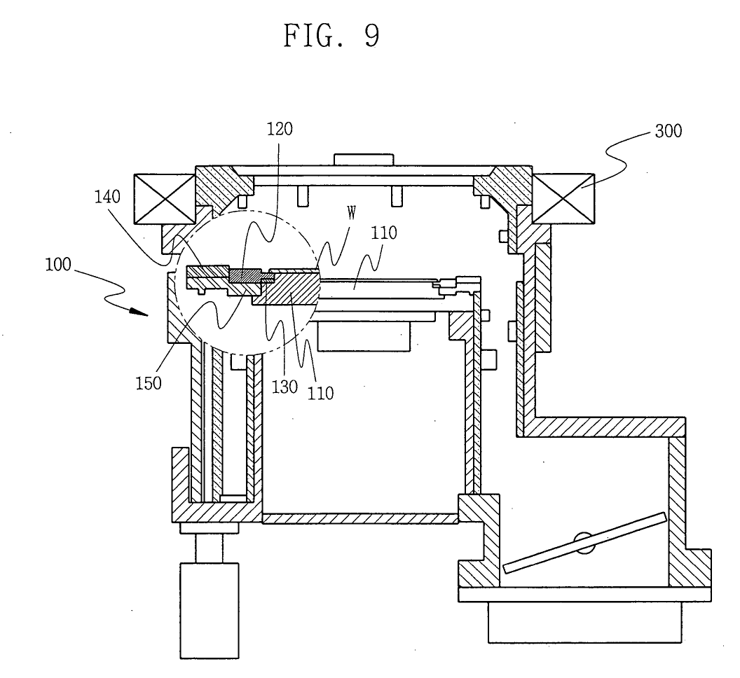

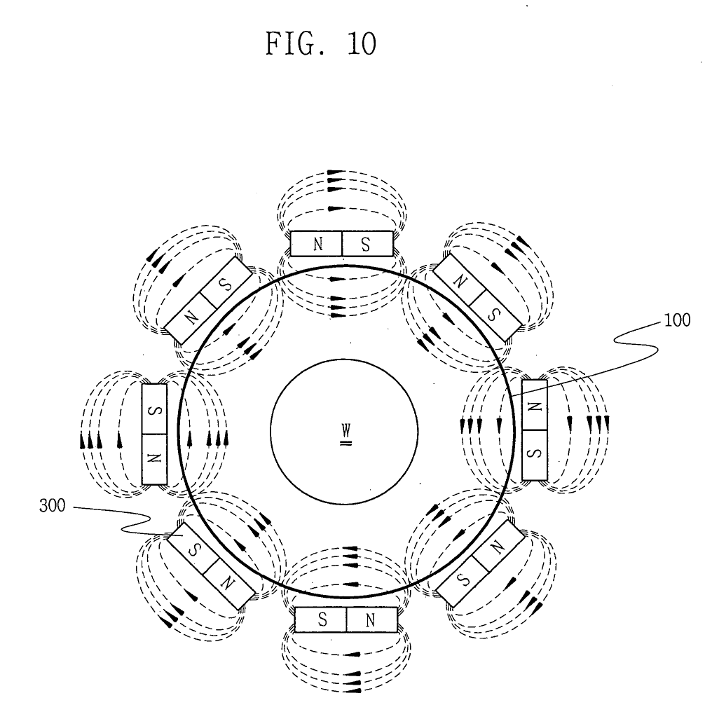

FIGS. 9 and 10 illustrate the configuration of a third exemplary embodiment of the invention.

Beneficially, electrostatic chuck 110, ring mounting part, vertical surface 112, edge ring member 120 (including outer part 121 and inner part 122), spacer member 130, focus ring 140, and shadow ring 150 have the same configurations and characteristics as described above in detail with respect to the first and second exemplary embodiments. Accordingly, a detailed discussion of these elements will not be repeated again here.

However, in the third exemplary embodiment, a plurality of magnet members 300 are provided along an upper portion of an outer wall of process chamber 100 at a position higher than a plasma formation area.

Here, each magnet member 300 is formed of mutually corresponding N and S poles. The magnet members 300 are arrayed in the same sequence along an outer wall of the process chamber 100 so that the N pole of each magnet is disposed closer to the S pole, than the N pole, of the preceding magnet as one proceeds circumferentially along the outer wall of process chamber 100.

A magnetic force having a downward direction is formed by a magnetic field generated between the N and S poles, and this magnetic force is contacted with the plasma in process chamber 100. Accordingly, the magnet members 300 are provided to accelerate plasma ions toward wafer W according to the Faraday principle, in similarity to the second exemplary embodiment.

At this time, the magnetic field formed on a peripheral portion of the outer wall of process chamber 100 is greater than the magnetic field formed in a center of process chamber 100. Thus, the plasma on an edge of wafer W can be made to be more vertically aligned than in the example shown in FIG. 2 above.

Furthermore, a formation range of the plasma is extended further by edge ring member 120, and when the magnetic field is in contact with the plasma, plasma ions are accelerated toward the wafer W so as to perform an etching having a vertical profile and sufficient depth.

Meanwhile, a primary magnetic field is formed in each magnet member 300 due to its N pole and S pole, but a parasitic magnetic field also may be formed due to the effects of adjacent magnet members 300. The magnetic field formed in a particular magnet member 300 due to adjacent magnet members 300 has a direction opposite to the primary magnetic field formed in the particular magnet member 300 itself. Thus it may be most desirous to make the magnet members 300 have a distance great enough to reduce or eliminate the influence of the magnetic field formed in adjacent magnet members 300.

[Fourth Exemplary Embodiment]

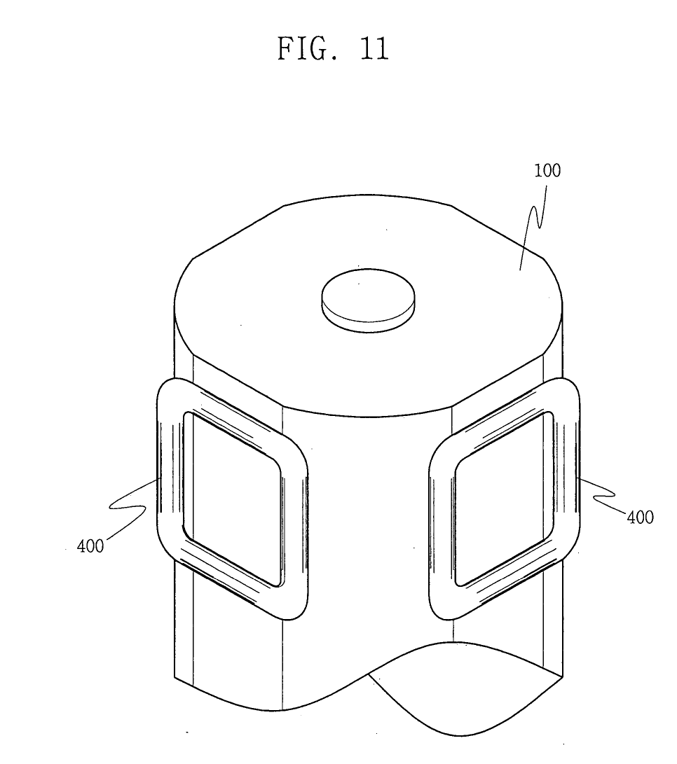

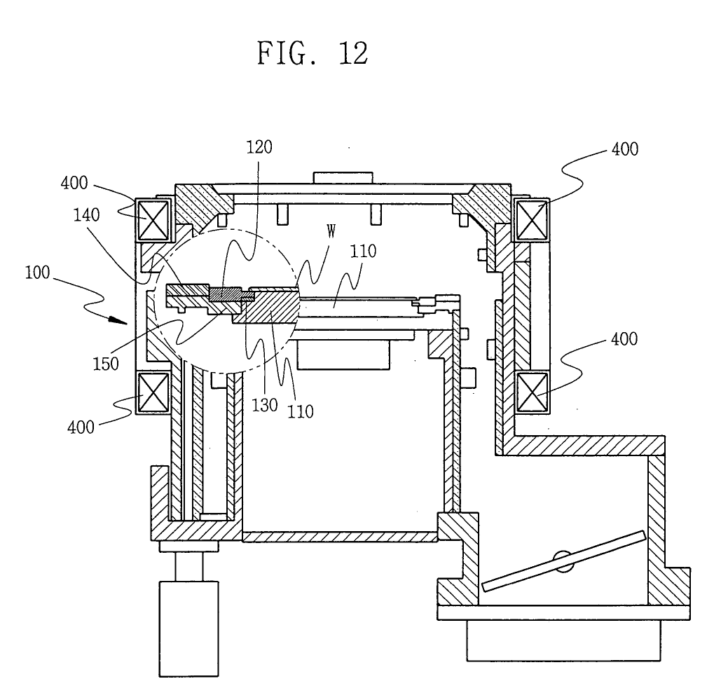

FIGS. 11 and 12 illustrate the configuration of a fourth exemplary embodiment.

Beneficially, electrostatic chuck 110, ring mounting part, vertical surface 112, edge ring member 120 (including outer part 121 and inner part 122), spacer member 130, focus ring 140, and shadow ring 150 have the same configurations and characteristics as described above in detail with respect to the first and second exemplary embodiments. Accordingly, a detailed discussion of these elements will not be repeated again here.

However, the fourth exemplary embodiment includes a plurality of electromagnet members 400 having a rectangular shape provided along an outer wall of process chamber 100 centering on a plasma formation area.

Electromagnet member 400 is formed by winding an electromagnetic coil onto an iron core of a rectangular ring shape, and such electromagnet members 400 are equipped along an outer wall of process chamber 100 so that a middle height portion of the electromagnet member 400 is positioned at a plasma formation area of the process chamber 100.

When a power source is applied to the electromagnet member 400 of rectangular shape, an electric field is in contact with the outer side of the plasma through the electromagnet member 400, and plasma ions are accelerated toward wafer W.

That is, when plasma ions are accelerated and collide with wafer W at an edge of wafer W, the verticality of the etched pattern is improved and the pattern can be formed to a sufficient depth.

According to exemplary embodiments described above, a structural improvement of an edge ring can extend a formation range of plasma formed on a wafer W such that a collision angle of plasma on an edge of wafer W has an almost vertical property, to thereby in turn improve the verticality of an etched pattern and simultaneously accelerate a collision speed of plasma at least at an edge of wafer thereby obtaining a sufficient etching to a depth required for the vertical property to prevent an error, such as a non-opening problem.

As described above, according to exemplary embodiments, an edge ring member formed of the same material as wafer W is extended further to the outside of the wafer, thus a formation range of plasma formed on the wafer W is also extended, to thereby increase the verticality of the collision angle through plasma ions and to simultaneously accelerate a collision speed of plasma ions at least at an edge of wafer W by a contact between a downward electric field or magnetic field and plasma ions. Accordingly, the verticality of the pattern formed at an edge of wafer W is improved, and at the same time, the etching can be performed to a required depth with a precise pattern.

Accordingly, an entirely uniform etching efficiency on a wafer W is obtained and productivity increases, enhancing reliability for products with economical advantages.

It will be apparent to those skilled in the art that modifications and variations can be made in the present invention without deviating from the spirit or scope of the invention. Thus, it is intended that the present invention cover any such modifications and variations of this invention provided they come within the scope of the appended claims and their equivalents. Accordingly, these and other changes and modifications are seen to be within the true scope of the invention as defined by the appended claims.

What is claimed is:

1. A semiconductor etching apparatus, comprising:
an electrostatic chuck within a process chamber, a circumferal area of a top portion of the electrostatic chuck being recessed by a fixed distance down to a fixed depth to form a stepped-down ring mounting part;
an edge ring member having an outer part and an inner part in one body, the outer part having a thickness greater than a height of a vertical surface of the ring mounting part of the electrostatic chuck, and the inner part being projected inwardly from an inner diameter surface of the outer part so as to be proximate to the vertical surface of the ring mounting part, where an upper surface and a lower surface of the inner part are stepped upward and downward, respectively, by a same height from inner diameter upper and lower surfaces of the outer part; and
a spacer member having a ring shape and being disposed on a horizontal surface of the ring mounting part of the electrostatic chuck, the spacer member being adapted to support a lower surface of the inner part of the edge ring member, and having a thickness that is the same as the height between the lower surface of the outer part and the upper surface of the inner part of the edge ring member.

2. The apparatus of claim 1, wherein a height from a lower surface of the outer part to an upper surface of the inner part of the edge ring member is the same as the same height as the vertical surface of the ring mounting part.

3. The apparatus of claim 1, wherein an inner diameter surface of the spacer member is adapted to be proximate to the vertical surface of the ring mounting part of the electrostatic chuck.

4. The apparatus of claim 1, further comprising a focus ring disposed outside of an outer circumference of the edge ring member.

5. A semiconductor etching apparatus, comprising:
an electrostatic chuck within a process chamber, a circumferal area of a top portion of the electrostatic chuck being recessed by a fixed distance down to a fixed depth to form a stepped-down ring mounting part;
an edge ring member having an outer part and an inner part in one body, the outer part having a thickness greater than a height of a vertical surface of the ring mounting part of the electrostatic chuck, and the inner part being projected inwardly from an inner diameter surface of the outer part so as to be proximate to the vertical surface of the ring mounting part, where an upper surface and a lower surface of the inner part are stepped upward and downward, respectively, by a same height from inner diameter upper and lower surfaces of the outer part;
a spacer member having a ring shape and being disposed on a horizontal surface of the ring mounting part of the electrostatic chuck, the spacer member being adapted to support a lower surface of the inner part of the edge ring member, and having a thickness that is the same as the height between the lower surface of the outer part and the upper surface of the inner part of the edge ring member; and
an electromagnet member provided around an outer wall of the process chamber at a position higher than a plasma formation region, the electromagnet member comprising a conductive coil wrapped around a ring-shaped core of magnetic material.

6. The apparatus of claim 5, wherein a height from a lower surface of the outer part to an upper surface of the inner part of the edge ring member is the same as the same height as the vertical surface of the ring mounting part.

7. The apparatus of claim 5, wherein an inner diameter surface of the spacer member is adapted to be proximate to the vertical surface of the ring mounting part of the electrostatic chuck.

8. The apparatus of claim 5, wherein the electromagnet member is adapted to provide an electric field having a downward direction in the process chamber when an electric current is applied thereto.

9. The apparatus of claim 5, further comprising a focus ring disposed outside of an outer circumference of the edge ring member.

10. A semiconductor etching apparatus, comprising
an electrostatic chuck within a process chamber, a circumferal area of a top portion of the electrostatic chuck being recessed by a fixed distance down to a fixed depth to form a stepped-down ring mounting part;
an edge ring member having an outer part and an inner part in one body, the outer part having a thickness greater than a height of a vertical surface of the ring mounting part of the electrostatic chuck, and the inner part being projected inwardly from an inner diameter surface of the outer part so as to be proximate to the vertical surface of the ring mounting part, where an upper surface and a lower surface of the inner part are stepped upward and downward, respectively, by a same height from inner diameter upper and lower surfaces of the outer part;
a spacer member having a ring shape and being disposed on a horizontal surface of the ring mounting part of the electrostatic chuck, the spacer member being adapted to support a lower surface of the inner part of the edge ring member, and having a thickness that is the same as the height between the lower surface of the outer part and the upper surface of the inner part of the edge ring member; and
a plurality of magnet members provided around an outer wall of the process chamber at a position higher than a plasma formation portion, the magnet members having a same polar orientation as each other proceeding around the outer wall of the process chamber such that an N pole of each magnet member is disposed closer to the S pole, than the N pole, of an adjacent magnet member.

11. The apparatus of claim 10, wherein a height from a lower surface of the outer part to an upper surface of the inner part of the edge ring member is the same as the same height as the vertical surface of the ring mounting part.

12. The apparatus of claim 10, wherein an inner diameter surface of the spacer member is adapted to be proximate to the vertical surface of the ring mounting part of the electrostatic chuck.

13. The apparatus of claim 10, wherein the magnet members are oriented so as to provide a magnetic field inside the process chamber having a downward direction.

14. The apparatus of claim 10, further comprising a focus ring disposed outside of an outer circumference of the edge ring member.

15. A semiconductor etching apparatus, comprising
an electrostatic chuck within a process chamber, a circumferal area of a top portion of the electrostatic chuck being recessed by a fixed distance down to a fixed depth to form a stepped-down ring mounting part;
an edge ring member having an outer part and an inner part in one body, the outer part having a thickness greater than a height of a vertical surface of the ring mounting part of the electrostatic chuck, and the inner part being projected inwardly from an inner diameter surface of the outer part so as to be proximate to the vertical surface of the ring mounting part, where an upper surface and a lower surface of the inner part are stepped upward and downward, respectively, by a same height from inner diameter upper and lower surfaces of the outer part;
a spacer member having a ring shape and being disposed on a horizontal surface of the ring mounting part of the electrostatic chuck, the spacer member being adapted to support a lower surface of the inner part of the edge ring member, and having a thickness that is the same as the height between the lower surface of the outer part and the upper surface of the inner part of the edge ring member; and
a plurality of electromagnet members provided along an outer wall of the process chamber, each of the electromagnet members comprising a conductive coil wrapped around a core of magnetic material and being adapted so that a middle of the electromagnet member is positioned corresponding to a plasma formation region within the process chamber.

16. The apparatus of claim 15, wherein a height from a lower surface of the outer part to an upper surface of the inner part of the edge ring member is the same as the same height as the vertical surface of the ring mounting part.

17. The apparatus of claim 15, wherein an inner diameter surface of the spacer member is adapted to be proximate to the vertical surface of the ring mounting part of the electrostatic chuck.

18. The apparatus of claim 15, wherein each electromagnet member is adapted to provide an electric field having a downward direction in the process chamber when an electric current is applied thereto.

19. The apparatus of claim 15, further comprising a focus ring disposed outside of an outer circumference of the edge ring member.
